(19) United States
(12) Patent Application Publication
(10) Pub. No.: US 2024/0387337 A1
(43) Pub. Date: Nov. 21, 2024

(54) ELECTRONIC DEVICE AND MANUFACTURING METHOD THEREOF

(71) Applicant: Innolux Corporation, Miaoli County (TW)

(72) Inventors: Ying-Jen Chen, Miaoli County (TW); Chih-Yung Hsieh, Miaoli County (TW); Wei-Lun Shieh, Miaoli County (TW)

(73) Assignee: Innolux Corporation, Miaoli County (TW)

(21) Appl. No.: 18/631,084

(22) Filed: Apr. 10, 2024

Related U.S. Application Data
(60) Provisional application No. 63/467,008, filed on May 17, 2023.

(30) Foreign Application Priority Data
Feb. 2, 2024 (CN) 202410150368.X

(51) Int. Cl. H01L 23/498; H01L 21/48; H01L 23/00; H01L 23/14; H01L 23/552; H01L 25/16

(52) U.S. Cl. CPC H01L 23/49822; H01L 21/4857; H01L 23/14; H01L 23/552; H01L 24/16; H01L 25/167; H01L 2224/16225; H01L 2924/15

(57) ABSTRACT

An electronic device and a manufacturing method thereof are provided. The manufacturing method of the electronic device includes forming a circuit substrate. Forming the circuit substrate includes providing a base material, wherein the base material has a first side and a second side opposite to each other. A contact pad is formed on the first side. An electronic element is provided. A conductive bump is formed on the contact pad, wherein the electronic element is bonded onto the circuit substrate via the conductive bump. A laser is applied to an area of the second side of the base material corresponding to the contact pad.

### CROSS-REFERENCE TO RELATED APPLICATION

This application claims the priority benefit of U.S. provisional application Ser. No. 63/467,008, filed on May 17, 2023 and China application serial no. 202410150368.X, filed on Feb. 2, 2024. The entirety of each of the above-mentioned patent applications is hereby incorporated by reference herein and made a part of this specification.

### BACKGROUND

### Technical Field

The disclosure relates to an electronic device and a manufacturing method thereof, and more particularly, to an electronic device having better structural reliability and a manufacturing method thereof.

### Description of Related Art

In the traditional reflow bonding process, all the members of the electronic device are put into the reflow oven together, and all the members are heated to bond the electronic elements and the circuit substrate. However, since all members need to be placed in the reflow oven, in addition to the circuit board warping after high-temperature reflow soldering, some electronic elements are also damaged because they may not withstand the high-temperature reflow soldering process.

### SUMMARY

The disclosure is directed to an electronic device and a manufacturing method thereof that may effectively reduce the thermal effects generated when heating circuit substrates and electronic elements, so that the electronic device may have better structural reliability.

According to an embodiment of the disclosure, a manufacturing method of an electronic device includes the following steps. A circuit substrate is formed. Forming the circuit substrate includes providing a base material, wherein the base material has a first side and a second side opposite to each other. A contact pad is formed on the first side. An electronic element is provided. A conductive bump is formed on the contact pad, wherein the electronic element is bonded onto the circuit substrate via a conductive bump. A laser is applied to an area of the second side of the base material corresponding to the contact pad.

According to an embodiment of the disclosure, an electronic device includes a circuit substrate, a conductive bump, and an electronic element. The circuit substrate includes a base material, a first metal layer, and a contact pad. The first metal layer is disposed on the base material, and the first metal layer has a first opening. The contact pad is disposed on the first metal layer and at least partially overlapped with the first opening. The conductive bump is disposed on the contact pad. The electronic element is disposed on the circuit substrate, wherein the contact pad is electrically connected to the electronic element via the conductive bump.

Based on the above, in an embodiment of the disclosure, the contact pad is formed on the first side of the base material, and the laser is applied to the area of the second side of the base material corresponding to the contact pad. That is, the contact pad is soldered back and forth via local heating by laser to effectively reduce the thermal effect generated when the circuit substrate and the electronic element are heated.

In order to make the above-mentioned features and advantages of the disclosure more comprehensible, the following specific embodiments are described in detail with reference to the accompanying drawings.

### BRIEF DESCRIPTION OF THE DRAWINGS

The accompanying drawings are included to further understand the disclosure, and the drawings are incorporated in the specification and constitute a part of the specification. The drawings illustrate embodiments of the disclosure and, together with the description, serve to explain principles of the disclosure.

FIG. 1A is a schematic cross-sectional view of an electronic device of an embodiment of the disclosure.

FIG. 1B is a three-dimensional schematic view of the circuit substrate in FIG. 1A.

FIG. 1C is a three-dimensional schematic view of a circuit substrate of an electronic device of another embodiment of the disclosure.

FIG. 2 is a schematic cross-sectional view of an electronic device of another embodiment of the disclosure.

FIG. 3 is a schematic cross-sectional view of an electronic device of another embodiment of the disclosure.

FIG. 4 is a schematic cross-sectional view of an electronic device of another embodiment of the disclosure.

FIG. 5 is a schematic cross-sectional view of an electronic device of another embodiment of the disclosure.

### DESCRIPTION OF THE EMBODIMENTS

Reference will now be made in detail to the exemplary embodiments of the disclosure, examples of which are illustrated in the accompanying drawings. Wherever possible, the same reference numerals are used in the drawings and descriptions to refer to the same or like portions.

The following description lists various embodiments of the present application to introduce the basic concepts of the present application, and is not intended to limit the content of the present application. The actual scope of the disclosure should be defined according to the claims. Hereinafter, reference will be made in detail to exemplary embodiments of the disclosure, and examples of the exemplary embodiments are illustrated in the figures. Wherever possible, the same reference numerals are used in the drawings and descriptions to refer to the same or like portions.

Certain terms are used throughout the specification and the appended claims of the disclosure to refer to particular members. Those skilled in the art should understand that sensing device manufacturers may refer to the same members under different names. This article does not intend to distinguish between those members that have the same function but have different names. In the following specification and claims, words such as “containing”, “comprising”, and “including” are open-ended words, so they should be interpreted as meaning “containing but not limited to . . . ”

The terminology mentioned in the specification, such as: “up”, “down”, “front”, “rear”, “left”, “right”, etc., are directions referring to the drawings. Therefore, the directional terms used are used for illustration, not for limiting the disclosure. In the drawings, each drawing depicts general features of methods, structures, and/or materials used in specific embodiments. However, these drawings should not be construed to define or limit the scope or nature covered by these embodiments. For example, for clarity, the relative dimension, thickness, and location of each film, area, and/or structure may be reduced or enlarged.

One structure (or layer, member, base material) described in the disclosure being located on/over another structure (or layer, member, base material) may mean that two the structures are adjacent and directly connected, or may mean that the two structures are adjacent but not directly connected. Indirect connection means that there is at least one intermediary structure (or intermediary layer, intermediary member, intermediary base material, or intermediary spacer) between the two structures. The lower surface of one structure is adjacent to or directly connected to the upper surface of the intermediary structure, and the upper surface of the other structure is adjacent to or directly connected to the lower surface of the intermediary structure. The intermediary structure may be formed by a single-layer or multi-layer physical structure or a non-physical structure, and there is no limit. In the disclosure, when a certain structure is disposed “on” another structure, it may mean that the certain structure is “directly” on the other structure, or it may mean that the certain structure is “indirectly” on the other structure. That is, at least one structure is sandwiched between the certain structure and the other structure.

The disclosure may be understood by referring to the following detailed description in conjunction with the accompanying drawings. It should be noted that in order to facilitate understanding to the reader and to simplify the drawings, the multiple drawings in the disclosure depict a part of the electronic device, and certain elements in the drawings are not drawn to actual scale. In addition, the quantity and dimension of each element in the figures are for illustration, and are not intended to limit the scope of the disclosure.

Certain terms are used throughout the specification and the appended claims of the disclosure to refer to particular elements. Those skilled in the art should understand that electronic equipment manufacturers may refer to the same elements under different names. This article does not intend to distinguish between those elements that have the same function but have different names.

In the following specification and claims, words such as “containing” and “including” are open-ended words, so they should be interpreted as meaning “containing but not limited to . . . ”

In addition, relative terms, such as “below” or “bottom” and “above” or “top”, may be used in the embodiments to describe the relative relationship of one element of the drawing to another element. It will be understood that if the device in the figures is turned upside down, elements described as being on the “lower” side are then elements described as being on the “upper” side.

In some embodiments of the disclosure, terms related to bonding, connecting, such as “connecting”, “interconnecting”, etc., unless otherwise specified, may mean that two structures are in direct contact, or may also mean that the two structures are not in direct (indirect) contact, and there are other structures disposed between the two structures. Moreover, the terms of bonding and connecting may also include the case where both structures are movable or both structures are fixed. Moreover, the term “coupling” includes the transfer of energy between two structures via direct or indirect electrical connection, or the transfer of energy between two separate structures via mutual induction.

It should be understood that, when an element or film is referred to as being “on” or “connected to” another element or film, it may be directly on or directly connected to this other element or layer, or there may be an intervening element or layer in between (indirect case). In contrast, when an element is referred to as being “directly on” or “directly connected to” another element or layer, there are no intervening elements or layers present.

The terms “about”, “equal to”, “equal” or “identical”, “substantially” or “roughly” are generally interpreted as being within 20% of a given value or range, or interpreted as being within 10%, 5%, 3%, 2%, 1%, or 0.5% of a given value or range.

As used herein, the terms “film” and/or “layer” may refer to any continuous or discontinuous structure and material (such as materials deposited by the methods disclosed herein). For example, films and/or layers may include two-dimensional materials, three-dimensional materials, nanoparticles, or even partial or complete molecular layers, or partial or complete atomic layers, or clusters of atoms and/or molecules. The film or the layer may include a material or a layer having pinholes, and may be at least partially continuous.

Furthermore, any two values or directions used for comparison may have certain errors. If the first value is equal to the second value, it implies that there may be an error of about 10% between the first value and the second value; if the first direction is perpendicular or “substantially” perpendicular to the second direction, the angle between the first direction and the second direction may be between 80 degrees and 100 degrees; if the first direction is parallel or “substantially” parallel to the second direction, the angle between the first direction and the second direction may be between 0 degrees and 10 degrees.

The ordinal numbers used in the specification and claims, such as “first”, “second”, etc., are used to modify an element. They do not themselves imply and represent that the element(s) have any previous ordinal quantity, and also do not represent the order of one element and another element, or the order of manufacturing methods. The use of these ordinal numbers is to clearly distinguish an element with a certain name from another element with the same name. The same terms may not be used in the claims and the specification, and accordingly, the first member in the specification may be the second member in the claims.

In the disclosure, the terms “the given range is from the first value to the second value” and “the given range falls within the range of the first value to the second value” mean that the given range includes the first value, the second value, and other values therebetween.

It should be understood that, according to an embodiment of the disclosure, optical microscope (OM), scanning electron microscope (SEM), film thickness profiler (α-step), ellipsometer, or other suitable methods may be used to measure the depth, thickness, width, or height of each element, or the spacing or distance between the elements. According to some embodiments, a scanning electron microscope may be used to obtain a cross-sectional structure image including the elements to be measured, and measure the depth, thickness, width, or height of each element, or the spacing or distance between the elements.

Unless otherwise defined, all terms (including technical and scientific terms) used herein have the same meaning as commonly understood by one of ordinary skill in the art to which this disclosure belongs. It may be understood that these terms, such as those defined in commonly used dictionaries, should be interpreted as having a meaning consistent with the background or context of the related techniques and the disclosure, and should not be interpreted in an idealized or overly formal manner, unless otherwise defined herein.

It should be noted that in the following embodiments, the technical features in several different embodiments may be replaced, recombined, and mixed to complete other embodiments without departing from the spirit of the disclosure.

An electronic device of the disclosure may include an electronic element. The electronic element may include a passive element, an active element, or a combination of the above, such as a capacitor, a resistor, an inductor, a varactor diode, a variable capacitor, a filter, a diode, a transistor, a sensor, a microelectromechanical system (MEMS), a liquid-crystal chip, etc., but the disclosure is not limited thereto. The diode may include a light-emitting diode or a non-light-emitting diode. The diode includes a P-N junction diode, a PIN diode, or a constant current diode. The LED may include, for example, an organic LED (OLED), a mini LED, a micro LED, or a quantum dot LED, fluorescence, phosphor, or other suitable materials, or a combination of the above, but the disclosure is not limited thereto. The sensor may include, for example, a capacitive sensor, an optical sensor, an electromagnetic sensor, a fingerprint sensor (FPS), a touch sensor, an antenna, or a pen sensor, but the disclosure is not limited thereto. The following uses a display device as an electronic device to explain the content of the disclosure, but the disclosure is not limited thereto. The electronic element may include a chip or an LED chip, and may be a chip made of silicon (Si), gallium arsenide (GaAs), gallium nitride (GaN), silicon carbide (SiC), sapphire, or a glass substrate, but the disclosure is not limited thereto. In another embodiment, the chip may include a semiconductor packaging element, such as a ball grid array (BGA) packaging element, a chip size package (CSP) element, a flip chip, or a 2.5D/3D semiconductor packaging element, but the disclosure is not limited thereto. In another embodiment, the chip may be any flip-chip bonded element, such as an integrated circuit (IC), a transistor, a silicon controlled rectifier, a valve, a thin-film transistor, a capacitor, an inductor, a variable capacitor, a filter, a resistor, a diode, a microelectromechanical system element (MEMS), a liquid-crystal chip, etc., but the disclosure is not limited thereto. Hereinafter, reference will be made in detail to exemplary embodiments of the disclosure, and examples of the exemplary embodiments are illustrated in the figures. Wherever possible, the same reference numerals are used in the drawings and descriptions to refer to the same or like portions. Hereinafter, reference will be made in detail to exemplary embodiments of the disclosure, and examples of the exemplary embodiments are illustrated in the figures. Wherever possible, the same reference numerals are used in the drawings and descriptions to refer to the same or like portions. The electronic device may include an imaging device, a laminating device, a display device, a backlight device, an antenna device, a sensing device, a tiling device, a packaging device, a touch electronic device (touch display), a curved electronic device (curved display), or a non-rectangular electronic device (free shape display), but the disclosure is not limited thereto. The electronic device may include, for example, liquid crystal, LED, fluorescence, phosphor, other suitable display media, or a combination of the above, but the disclosure is not limited thereto. The display device may be a non-self-illuminating display device or a self-illuminating display device. The antenna device may be a liquid-crystal-type antenna device or a non-liquid-crystal-type antenna device, and the sensing device may be a sensing device that senses capacitance, light, heat energy, or ultrasonic waves, but the disclosure is not limited thereto. The tiling device may be, for example, a display tiling device or an antenna tiling device, but the disclosure is not limited thereto. The packaging device may be a wafer-level package (WLP) device or a panel-level package (PLP) device, but the disclosure is not limited thereto. The packaging device may be a chip-first or a chip-last/RDL first packaging device. It should be noted that the electronic device may be any combination of the above, but the disclosure is not limited thereto. The electronic device may be a bendable or flexible electronic device. It should be noted that the electronic device may be any combination of the above, but the disclosure is not limited thereto. In addition, the shape of the electronic device may be rectangular, circular, polygonal, with curved edges, or other suitable shapes. The electronic device may have a peripheral system such as a drive system, a control system, a light source system, a shelf system, etc. to support a display device, an antenna device, or a tiling device. It should be noted that in the following embodiments, the features in several different embodiments may be replaced, recombined, and mixed to complete other embodiments without departing from the spirit of the disclosure. As long as the features between the embodiments do not violate the spirit of the disclosure or conflict with each other, they may be mixed and used arbitrarily.

Unless otherwise defined, all terms (including technical and scientific terms) used herein have the same meaning as commonly understood by one of ordinary skill in the art to which this disclosure belongs. It may be understood that these terms, such as those defined in commonly used dictionaries, should be interpreted as having a meaning consistent with the background or context of the related techniques and the disclosure, and should not be interpreted in an idealized or overly formal manner, unless otherwise defined in the embodiments of the disclosure.

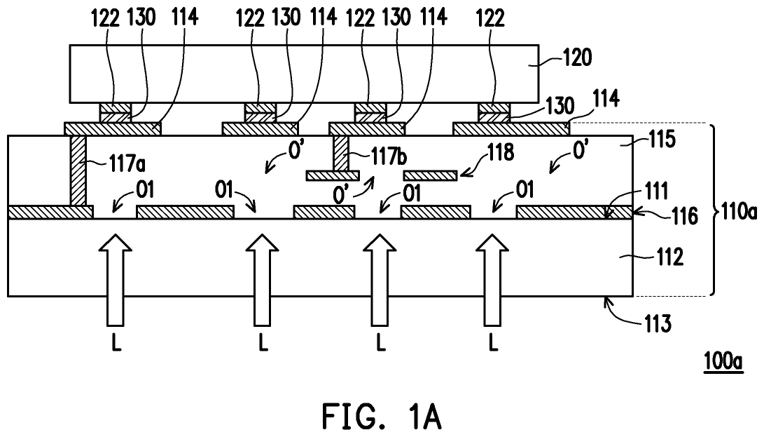

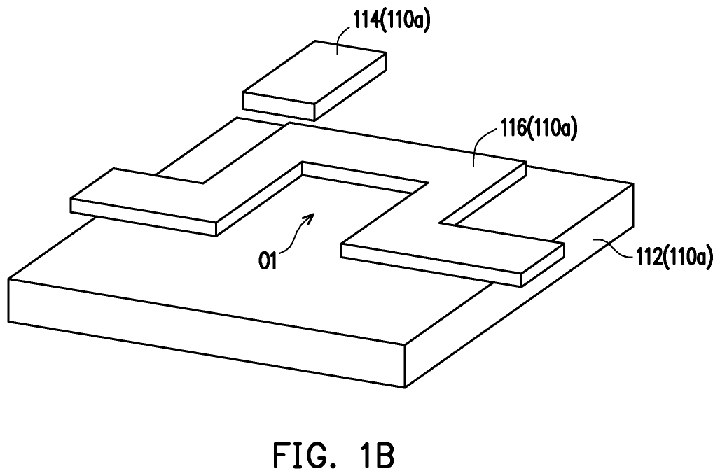

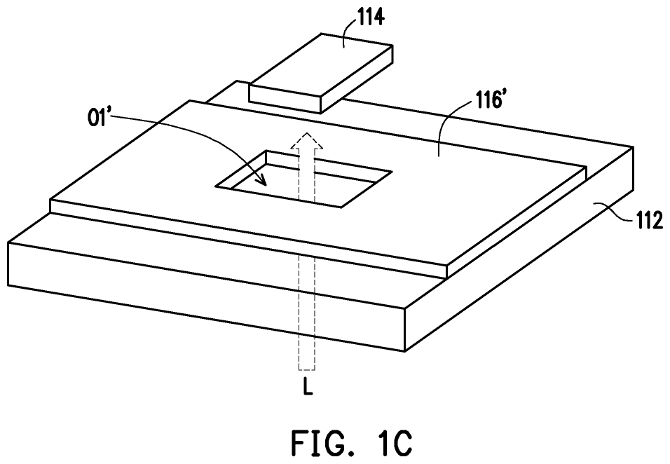

FIG. 1A is a schematic cross-sectional view of an electronic device of an embodiment of the disclosure. FIG. 1B is a three-dimensional schematic view of the circuit substrate in FIG. 1A. FIG. 1C is a three-dimensional schematic view of a circuit substrate of an electronic device of another embodiment of the disclosure.

Please refer to FIG. 1A first. Regarding the manufacturing method of the electronic device of the present embodiment, first, a circuit substrate 110a is formed. In the step of forming the circuit substrate 110a, first, a base material 112 is provided, wherein the base material 112 has a first side 111 and a second side 113 opposite to each other. In an embodiment, the base material 112 is, for example, a glass substrate, a silicon wafer, a glass fiber (FR4) substrate, or other substrates with high transmittance, but the disclosure is not limited thereto.

Next, the first metal layer 116 is formed on the first side 111 of the base material 112. In an embodiment, the first metal layer 116 may be formed by sputtering or applying a metal film, but the disclosure is not limited thereto. Right after, the first metal layer 116 is patterned to form a metal pattern and a first opening O1, wherein the patterning is, for example, etching the metal layer, but the disclosure is not limited thereto. That is, a portion of the first metal layer 116 is removed via patterning to form the first opening O1 exposing a portion of the first side 111 of the base material 112. In an embodiment, please refer to FIG. 1B, the first metal layer 116 may be, for example, a non-closed U-shaped pattern, and the first opening O1 is a non-closed opening, but the disclosure is not limited thereto. In another embodiment, please refer to FIG. 1C. A first metal layer 116′ is also a closed ring structure, and the shape of a first opening O1′ is embodied as a closed rectangle, but the disclosure is not limited thereto.

Next, a second metal layer 118 may be optionally formed on the first metal layer 116. In an embodiment, the second metal layer 118 may be formed by sputtering or applying a metal film, but the disclosure is not limited thereto. Next, the second metal layer 118 is patterned to form an opening O′ exposing a portion of the first side 111 of the base material 112. Next, a via hole 117a connected to the first metal layer 116 and a via hole 117b connected to the second metal layer 118 are formed.

Lastly, please refer to FIG. 1A and FIG. 1B at the same time. A contact pad 114 is formed on the first side 111 of the base material 112, wherein at least portion of the contact pad 114 is overlapped with the first opening O1 of the first metal layer 116. At this time, the first metal layer 116, the second metal layer 118, and the contact pad 114 are all located on the first side 111 of the base material 112, the first metal layer 116 is located between the base material 112 and the contact pad 114, and the second metal layer 118 is located between the first metal layer 116 and the contact pad 114. Furthermore, the first metal layer 116, the second metal layer 118, and the contact pad 114 may be electrically isolated by forming an insulating layer 115. In an embodiment, the contact pad 114 may be formed on the outermost insulating layer 115 of the circuit substrate 110a, but the disclosure is not limited thereto. In an embodiment, the material of the insulating layer 115 is, for example, an inorganic material, an organic material, or a combination thereof. For example, the insulating layer 115 may be a stack of multiple layers of an inorganic material or a stack of an organic material and an inorganic material. The inorganic material may include silicon nitride, silicon oxide, or silicon oxynitride, but the disclosure is not limited thereto. The electrical connection between the first metal layer 116, the second metal layer 118, and the contact pad 114 may be via the via hole 117a and the via hole 117b, wherein the contact pad 114 and the first metal layer 116 may be electrically connected via the via hole 117a, and the contact pad 114 and the second metal layer 118 may be electrically connected via the via hole 117b. At this point, the production of the circuit substrate 110a is completed.

In an embodiment, the circuit substrate 110a may include a base material, a metal layer, an insulation layer, a material layer, or any combination of the above. In an embodiment, the metal layer (e.g., the first metal layer 116 and the second metal layer 118) may be, for example, a redistribution layer (RDL), but the disclosure is not limited thereto. In an embodiment, regardless of the shape of the opening of the metal layer, as long as there is no metal pattern, it is part of the opening described in the present embodiment. Furthermore, at least a portion of the contact pad 114 may be overlapped with openings of different metal layers or openings of other material layers with poor transmittance, so as to reduce the probability that subsequent laser irradiation may not be performed. Moreover, it should be mentioned that, in the present embodiment, the circuit substrate 110a is formed with two metal layers (i.e., the first metal layer 116 and the second metal layer 118) and the contact pad 114 as an example, but the disclosure is not limited thereto. In other embodiments, the circuit substrate may also have one metal layer and contact pads, or two or more metal layers and contact pads. As long as at least a portion of the contact pads 114 is overlapped with the openings of the metal layer, it is within the scope of the present embodiment.

Next, please refer to FIG. 1A again, an electronic element 120 is provided. In an embodiment, the electronic element 120 may be, for example, an integrated circuit (IC), a capacitor, an inductor, a resistor, a diode, a light-emitting diode, or a varactor, etc. In an embodiment, the electronic element 120 may be, for example, a light-emitting diode, and different light-emitting diodes may emit different lights. For example, the light-emitting diode may respectively emit red light, green light, and blue light. In an embodiment, all light-emitting diodes on the circuit substrate may emit the same light. Next, a conductive bump 130 is formed on the contact pad 114, wherein a pad 122 of the electronic element 120 is bonded onto the circuit substrate 110a via the conductive bump 130. In an embodiment, the conductive bump 130 is, for example, solder, but the disclosure is not limited thereto.

Lastly, a laser L is applied to the area of the second side 113 of the base material 112 corresponding to the contact pad 114, so that the contact pad 114 is locally heated by the laser L and soldered back and forth, so that the electronic element 120 may be bonded onto the circuit substrate 110a. That is, by reducing the metal pattern and/or the material pattern with poor transmittance in the reflow path of the laser L, the laser L heats from the second side 113 of the base material 112 corresponding to the contact pad 114. Since the laser L is irradiated from the second side 113 of the base material 112 toward the first side 111, and the laser L may be irradiated to the contact pad 114 via the first opening O1 of the first metal layer 116, compared with the existing techniques where all members of all electronic devices are put into a reflow furnace for complete heating, in the present embodiment, the contact pad 114 of the circuit substrate 110a is locally heated by the laser L to effectively reduce the thermal effect generated when the circuit substrate 110a and the electronic element 120 are heated. At this point, the production of an electronic device 100a is completed.

Structurally, please refer to FIG. 1A again. In the present embodiment, the electronic device 100a includes the circuit substrate 110a, the conductive bump 130, and the electronic component 120. The circuit substrate 110a includes the base material 112, the first metal layer 116, and the contact pad 114. The first metal layer 116 is disposed on the base material 112, and the first metal layer 116 has the first opening O1. The contact pad 114 is disposed on the first metal layer 116 and at least partially overlapped with the first opening O1. The conductive bump 130 is disposed on the contact pad 114. The electronic element 120 is disposed on the circuit substrate 110a, wherein the contact pad 114 is electrically connected to the electronic element 120 via the conductive bump 130.

In addition, the circuit substrate 110a of the present embodiment further includes the second metal layer 118, wherein the second metal layer 118 is disposed on the first metal layer 116 and located on the first side 111 of the base material 112. The electronic element 120 may have a plurality of pads 122, and different pads 122 may receive or/and send different signals, such as power signals, ground signals, data signals, scan signals, etc. In an embodiment, when the electronic device 100a is used as an antenna device, the first metal layer 116 may be, for example, a ground metal layer, wherein the contact pad 114 is electrically connected to the first metal layer 116 via the via hole 117a to receive the ground signal, but the disclosure is not limited thereto. In addition, the contact pad 114 may be electrically connected to the second metal layer 118 via the via hole 117b.

It must be noted here that the following embodiments adopt the reference numerals and a portion of the content of the above embodiments, wherein the same reference numerals are used to represent the same or similar elements, and the description of the same technical content is omitted. For the description of the omitted portions, reference may be made to the above embodiments, which is not repeated in the following embodiments.

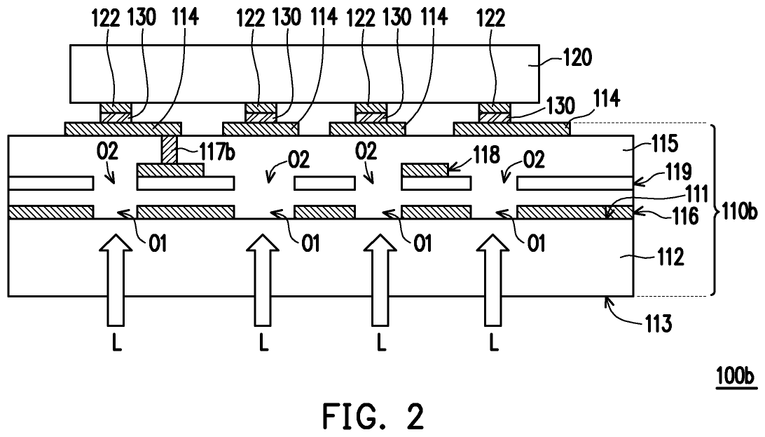

FIG. 2 is a schematic cross-sectional view of an electronic device of another embodiment of the disclosure. Please refer to FIG. 1A and FIG. 2 at the same time. An electronic device 100b of the present embodiment is similar to the electronic device 100a of FIGS. 1A and 1s not described again here. The difference between FIG. 1A and FIG. 2 is that in the present embodiment, the step of forming the circuit substrate 110b also includes forming a material layer 119 on the first metal layer 116, wherein the laser transmittance of the material layer 119 is less than or equal to 30%. In an embodiment, the laser transmittance of the material layer 119 is greater than or equal to the laser transmittance of the first metal layer 116. Here, the laser transmittance T is defined as T=(emitted light/incident light)*100%. The material of the material layer 119 is, for example, an organic material, such as polypropylene (PP), Ajinomoto build-up film (ABF), or perfluoroalkoxy (PFA), but the disclosure is not limited thereto.

Next, the material layer 119 is patterned to form a second opening O2. That is, a portion of the material layer 119 is removed via patterning to form the second opening O2. The second opening O2 of the material layer 119, regardless of the shape thereof, as long as there is no material pattern, is part of the second opening O2 of the present embodiment. In an embodiment, in the cross-sectional direction, the diameter of the second opening O2 is equal to the diameter of the first opening O1, and the second opening O2 is overlapped with the first opening O1, but the disclosure is not limited thereto. Next, the second metal layer 118 is formed on the first metal layer 116, wherein the material layer 119 is located between the first metal layer 116 and the second metal layer 118. Next, the via hole 117b connected to the second metal layer 118 is formed. Lastly, please refer to FIG. 2 again. The contact pad 114 is formed on the first side 111 of the base material 112, wherein at least a portion of the contact pad 114 is overlapped with the first opening O1 of the first metal layer 116 and the second opening O2 of the material layer 119. At this point, the production of the circuit substrate 110b is completed.

Next, please refer to FIG. 2 again, the electronic element 120 is provided. Next, the conductive bump 130 is formed on the contact pad 114, wherein the pad 122 of the electronic element 120 is bonded onto the circuit substrate 110b via the conductive bump 130. Lastly, the laser L is applied to the area of the second side 113 of the base material 112 corresponding to the contact pad 114, so that the contact pad 114 is locally heated by the laser L and soldered back and forth, so that the electronic element 120 may be bonded onto the circuit substrate 110b. In the disclosure, since at least a portion of the contact pad 114 may be overlapped with openings of different metal layers and/or openings of other material layers with poor transmittance, the probability that subsequent laser irradiation may not be performed may be reduced. That is, by reducing the metal pattern and/or the material pattern with poor transmittance in the reflow path of the laser L, the laser L heats from the second side 113 of the base material 112 corresponding to the contact pad 114. Since the laser light L is irradiated from the second side 113 of the base material 112 toward the first side 111, and the laser L may be irradiated to the contact pad 114 via the first opening O1 of the first metal layer 116 and the second opening O2 of the material layer 119 to locally heat the contact pad 114, the thermal effect generated when the circuit substrate 110a and the electronic element 120 are heated may be effectively reduced. At this point, the production of the electronic device 100b is completed.

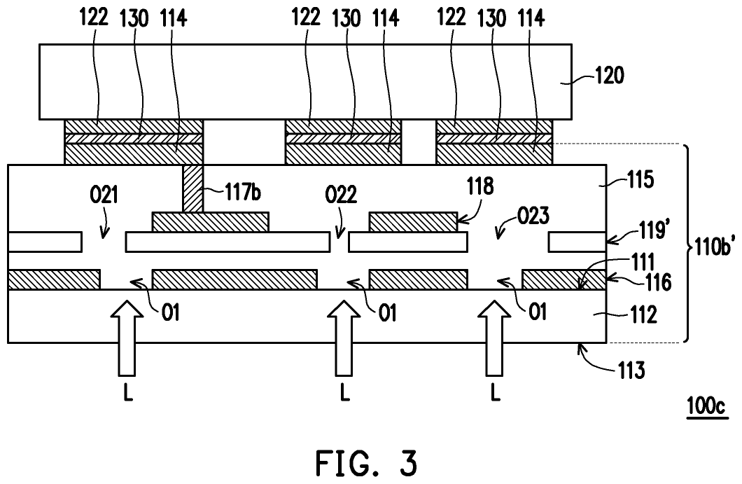

FIG. 3 is a schematic cross-sectional view of an electronic device of another embodiment of the disclosure. Please refer to FIG. 2 and FIG. 3 at the same time. An electronic device 100c of the present embodiment is similar to the electronic device 100b of FIG. 2 and is not described again here. The difference between FIG. 2 and FIG. 3 is that in the present embodiment, the first opening O1 of the first metal layer 116 of a circuit substrate 110b′ is at least partially overlapped with second openings O21, O22, and O23 of a material layer 119′. Furthermore, in the cross-sectional direction, a side edge of the second opening O21 of the material layer 119′ may be staggered from the edge of the first opening O1 of the first metal layer 116 at the same side, for example, and the second opening O21 is at least partially overlapped with the first opening O1. For example, in the cross-sectional direction, the right side edge of the second opening O21 is staggered from the right side edge of the first opening O1, and/or the left side edge of the second opening O21 is staggered from the left side edge of the first opening O1. The diameter of the second opening O22 is less than the diameter of the first opening O1. For example, the orthographic projection of the second opening O22 on the base material 112 is within the orthographic projection of the first opening O1 on the base material 112. That is, the second opening O22 and the first opening O1 are at least partially overlapped in the cross-sectional direction. The diameter of the second opening O23 is greater than the diameter of the first opening O1. For example, the orthographic projection of the first opening O1 on the base material 112 is within the orthographic projection of the second opening O23 on the base material 112. That is, the second opening O23 and the first opening O1 are at least partially overlapped in the cross-sectional direction.

In other words, in an embodiment, the first opening O1 and the second openings O21, O22, and O23 corresponding to the same contact pad 114 do not need to be aligned with each other, and may have different sizes. Furthermore, under the same cross-section, the opening sizes of different layers corresponding to the positions of the contact pads 114 may be the same or different. For example, the layer-level openings closer to the contact pads 114 may be less than or equal to the openings farther away from the contact pads 114, but the disclosure is not limited thereto. In addition, under the same cross-section, the opening edges of different layers corresponding to the positions of the contact pads 114 may also be aligned or staggered, but the disclosure is not limited thereto.

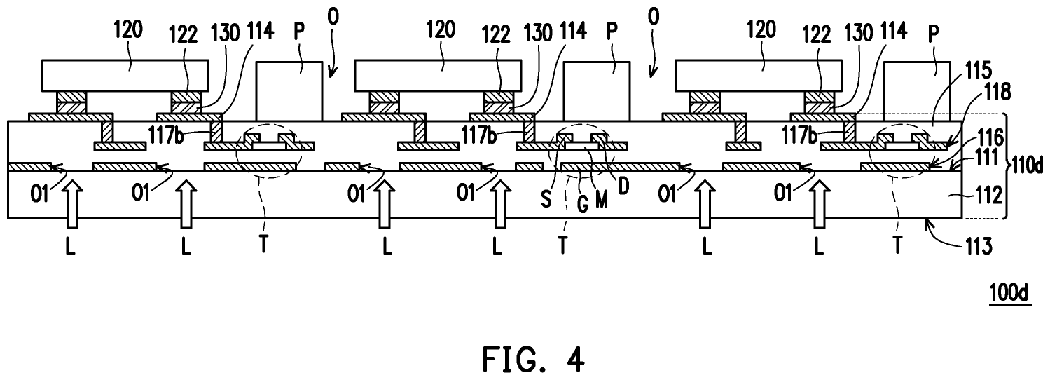

FIG. 4 is a schematic cross-sectional view of an electronic device of another embodiment of the disclosure. Please refer to FIG. 1A and FIG. 4 at the same time. An electronic device 100d of the present embodiment is similar to the electronic device 100a of FIGS. 1A and 1s not described again here. The difference between FIG. 1A and FIG. 4 is that in the present embodiment, the circuit substrate 110d further includes a transistor T disposed on the base material 112. In an embodiment, the transistor T is electrically connected to the electronic element 120. In an embodiment, the transistor T is, for example, formed by a semiconductor layer M, a gate G (defined by the local first metal layer 116 directly below the semiconductor layer M) and a source S and a drain D (defined by the local second metal layer 118 covering the semiconductor layer M). In an embodiment, the transistor T may be, for example, amorphous silicon TFT (a-Si TFT), low-temperature polysilicon TFT (LTPS TFT), InGaZnO (IGZO) TFT, or low-temperature polycrystalline oxide (LTPO), but the disclosure is not limited thereto. In addition, in the present embodiment, the electronic device 100d further includes a light-shielding layer P disposed on the circuit substrate 110d. In an embodiment, the light-shielding layer P may be disposed between adjacent electronic elements 120 in the cross-sectional direction. For example, when the electronic device 100d is used as a display device, the light-shielding layer P may be used as a pixel defining layer and includes a plurality of openings O for accommodating electronic elements 120 (for example, LEDs), so that in the top view direction, the area of the openings O may be used to define one pixel or sub-pixel of the display device 1, but the disclosure is not limited thereto. In an embodiment, the material of the light-shielding layer P may include a light-shielding material, wherein the light-shielding material may include, for example, a photoresist material, an ink material, a pigment, a dye, or other suitable materials. In an embodiment, the light-shielding layer P may be at least partially overlapped with the transistor T, but the disclosure is not limited thereto.

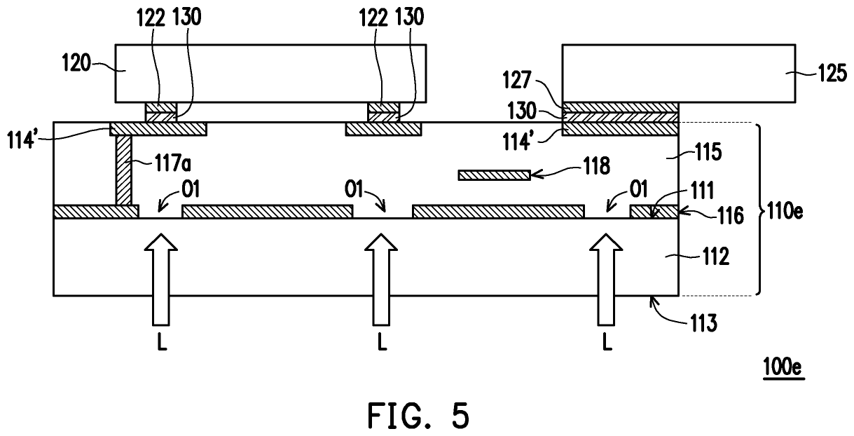

FIG. 5 is a schematic cross-sectional view of an electronic device of another embodiment of the disclosure. Please refer to FIG. 1A and FIG. 5 at the same time. An electronic device 100e of the present embodiment is similar to the electronic device 100a of FIGS. 1A and 1s not described again here. The difference between FIG. 1A and FIG. 4 is that in the present embodiment, a contact pad 114′ of the circuit substrate 110e is embedded in the outermost insulating layer 115 of the circuit substrate 110e. Furthermore, in the present embodiment, different electronic elements 120 and 125 may be electrically connected to each other via the contact pad 114′ of the circuit substrate 110e. In an embodiment, the electronic element 125 (such as a driving integrated circuit) may transmit the driving signal to the electronic element 120 (such as an LED). In an embodiment, the light-shielding layer P may be disposed between the electronic element 125 and the electronic element 120 in the cross-sectional direction, but the disclosure is not limited thereto.

Based on the above, in an embodiment of the disclosure, the contact pad is formed on the first side of the base material, and the laser is applied to the area of the second side of the base material corresponding to the contact pad. That is, the contact pad is soldered back and forth via local heating by laser to effectively reduce the thermal effect generated when the circuit substrate and the electronic element are heated. Lastly, it should be noted that the above embodiments are used to describe the technical solution of the disclosure instead of limiting it. Although the disclosure has been described in detail with reference to each embodiment above, those having ordinary skill in the art should understand that the technical solution recited in each embodiment above may still be modified, or some or all of the technical features thereof may be equivalently replaced. These modifications or replacements do not make the essence of the corresponding technical solutions depart from the scope of the technical solution of each embodiment of the disclosure.

What is claimed is:

1. A manufacturing method of an electronic device, comprising:
forming a circuit substrate, comprising:
providing a base material, wherein the base material has a first side and a second side opposite to each other; and
forming a contact pad on the first side;
providing an electronic element;
forming a conductive bump on the contact pad, wherein the electronic element is bonded onto the circuit substrate via the conductive bump; and
applying a laser to an area of the second side of the base material corresponding to the contact pad.

2. The manufacturing method of the electronic device of claim 1, wherein the step of forming the electronic substrate further comprises:
forming a first metal layer on the first side of the base material, wherein the first metal layer is between the base material and the contact pad; and
patterning the first metal layer to form a first opening, and at least a portion of the contact pad is overlapped with the first opening.

3. The manufacturing method of the electronic device of claim 2, wherein the step of forming the electronic substrate further comprises:
forming a material layer on the first metal layer; and
patterning the material layer to form a second opening, and at least a portion of the contact pad is overlapped with the second opening, wherein a laser transmittance of the material layer is less than or equal to 30%.

4. The manufacturing method of the electronic device of claim 3, wherein in a cross-sectional direction, a side edge of the second opening is staggered from an edge of the first opening at a same side.

5. The manufacturing method of the electronic device of claim 2, wherein the step of forming the electronic substrate further comprises:
forming a second metal layer on the first metal layer, wherein the second metal layer is electrically connected to the contact pad.

6. The manufacturing method of the electronic device of claim 5, wherein the first metal layer and the second metal layer are respectively redistribution layers.

7. The manufacturing method of the electronic device of claim 5, wherein the step of forming the electronic substrate further comprises:
forming a plurality of via holes to electrically connect the first metal layer and the contact pad and the second metal layer and the contact pad respectively.

8. The manufacturing method of the electronic device of claim 2, wherein a shape of the first metal layer comprises a non-closed U-shaped pattern or a closed loop pattern.

9. The manufacturing method of the electronic device of claim 1, wherein the substrate comprises a glass substrate, a silicon wafer, or a glass fiber substrate.

10. The manufacturing method of the electronic device of claim 1, wherein the electronic element comprises an integrated circuit, a capacitor, an inductor, a resistor, a diode, a light-emitting diode, or a varactor diode.

11. An electronic device, comprising:
a circuit substrate, comprising:
a base material;
a first metal layer disposed on the base material, and the first metal layer has a first opening; and
a contact pad disposed on the first metal layer and at least partially overlapped with the first opening;
a conductive bump disposed on the contact pad; and
an electronic element disposed on the circuit substrate, wherein the contact pad is electrically connected to the electronic element via the conductive bump.

12. The electronic device of claim 11, wherein the circuit substrate further comprises a material layer disposed on the first metal layer, the material layer comprises a second opening, the contact pad is at least partially overlapped with the first opening, and the first opening is at least partially overlapped with the second opening, wherein a laser transmittance of the material layer is less than or equal to 30%.

13. The electronic device of claim 12, wherein a material of the material layer comprises polypropylene (PP), Ajinomoto build-up film (ABF), or perfluoroalkoxy (PFA).

14. The electronic device of claim 12, wherein in a cross-sectional direction, a side edge of the second opening is staggered from an edge of the first opening at a same side.

15. The electronic device of claim 11, wherein the circuit substrate further comprises a transistor disposed on the base material and electrically connected to the electronic element.

16. The electronic device of claim 15, wherein the transistor comprises amorphous silicon TFT (a-Si TFT), low-temperature polysilicon TFT (LTPS TFT), InGaZnO (IGZO) TFT, or low-temperature polycrystalline oxide (LTPO).

17. The electronic device of claim 11, further comprising:
a light-shielding layer disposed on the circuit substrate.

18. The electronic device of claim 17, wherein a material of the light-shielding layer comprises a photoresist material, an ink material, a pigment, or a dye.

19. The electronic device of claim 11, wherein the substrate comprises a glass substrate, a silicon wafer, or a glass fiber substrate.

20. The electronic device of claim 11, wherein the electronic element comprises an integrated circuit, a capacitor, an inductor, a resistor, a diode, a light-emitting diode, or a varactor diode.
